(19) United States
(12) Patent Application Publication
(10) Pub. No.: US 2007/0108502 A1
(43) Pub. Date: May 17, 2007

(54) Nanocrystal silicon quantum dot memory device

(75) Inventors: Tingkai Li, Vancouver, WA (US); Sheng Teng Hsu, Camas, WA (US); Lisa H. Stecker, Vancouver, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/281,955

(22) Filed: Nov. 17, 2005

(51) Int. Cl. H01L 29/788; H01L 21/336; G11C 16/04

(52) U.S. Cl. 257/316; 438/257; 438/266; 438/962; 365/185.01; 977/721; 977/774; 977/936

(57) ABSTRACT

A nanocrystal silicon (Si) quantum dot memory device and associated fabrication method have been provided. The method comprises: forming a gate (tunnel) oxide layer overlying a Si substrate active layer; forming a nanocrystal Si memory film overlying the gate oxide layer, including a polycrystalline Si (poly-Si)/Si dioxide stack; forming a control Si oxide layer overlying the nanocrystal Si memory film; forming a gate electrode overlying the control oxide layer; and, forming source/drain regions in the Si active layer. In one aspect, the nanocrystal Si memory film is formed by depositing a layer of amorphous Si (a-Si) using a chemical vapor deposition (CVD) process, and thermally oxidizing a portion of the a-Si layer. Typically, the a-Si deposition and oxidation processes are repeated, forming a plurality of poly-Si/Si dioxide stacks (i.e., 2 to 5 poly-Si/Si dioxide stacks).

### BACKGROUND OF THE INVENTION

1. Field of the Invention

This invention generally relates to integrated circuit (IC) fabrication and, more particularly, to a flash memory device that uses a nanocrystalline quantum dot memory film.

2. Description of the Related Art

Flash memory is non-volatile, which means that it does not need power to maintain its memory state. Flash memory offers relatively fast read access times, and is more shock resistant than a hard disk. A typical flash memory system only permits one location at a time to be erased or written. Therefore, higher overall speeds are obtained when the system architecture permits multiple reads to take place simultaneous with a single write.

Flash memory comes in two forms, either NOR or NAND flash, referring to logic gate used in each cell. One of the primary problems with this type of memory is that the cells “wear out” after many erase operations, due to wear on the insulating or tunneling oxide layer around the charge storage mechanism used to store data. A typical NOR flash memory unit wears out after 10,000-100,000 erase/write operations, a typical NAND flash memory after 1,000,000.

Flash memory is essentially an NMOS transistor with an additional conductor suspended between the gate and source/drain terminals. This variation is called the Floating-Gate Avalanche-Injection Metal Oxide Semiconductor (FAMOS) transistor.

Flash memory stores information in an array of floating gate transistor, called “cells”, each of which conventionally stores one bit of information. Inside a floating gate MOSFET, the main components are a control gate, floating gate, and the thin oxide layer. When a floating gate MOSFET is given an electrical charge, that charge is trapped in the insulating thin oxide layer through a process known as Fowler-Nordheim tunneling. Newer flash memory devices, sometimes referred to as multi-level cell devices, can store more than 1 bit per cell, by varying the number of electrons placed on the floating gate of a cell.

In NOR flash, each cell looks similar to a conventional MOSFET, except that it has two gates instead of just one. One gate is the control gate (CG) as in a conventional MOS transistor, but the second is a floating gate (FG) that is insulated all around by an oxide layer. The FG is between the CG and the substrate. Because the FG is isolated by its insulating oxide layer, any electrons placed within are trapped and act as a store of information. When electrons are in the FG, they modify (partially cancel out) the electric field coming from the CG, which modifies the threshold voltage (Vₜ) of the cell. Thus, when the cell is “read” by placing a specific voltage on the CG, electric current either flows or not, depending on the Vₜ of the cell, which is controlled by the number of electrons on the FG. This presence or absence of current is sensed and translated into 1's and 0's, reproducing the stored data. In a multi-level cell device, which stores more than 1 bit of information per cell, the amount of current flow is sensed, rather than simply the presence or absence of current, in order to determine the number of electrons stored on the FG.

A NOR flash cell is programmed (set to a specified data value) by starting up electrons flowing from the source to the drain. Then, a large voltage placed on the CG provides a strong enough electric field to “suck them up” into the FG, a process called hot-electron injection. To erase (reset to all 1's, in preparation for reprogramming) a NOR flash cell, a large voltage differential is placed between the CG and source, which pulls the electrons off through quantum tunneling. All of the memory cells in a block must be erased at the same time. NOR programming, however, can generally be performed one byte or word at a time. NAND flash uses tunnel injection for writing and tunnel release for erasing.

As noted above, a fundamental problem associated with flash memory is the wear factor. This problem is typically due to the non-uniformity of the insulating oxide. If there is a weak spot, such that the leakage current density at that spot is larger than in the adjacent areas, all of the stored charges in the floating gate are liable to leak. This problem increases with the thinning of the oxide thickness. Thus, it is difficult to reduce the size, or increase the density of a flash memory.

### SUMMARY OF THE INVENTION

If the floating gate of a flash memory is replaced with nano particles, a weak spot in an insulating oxide layer only affects one adjacent nano particle, and has no effect on the other storage particles. Therefore, the thickness of both the tunnel (gate) oxide and the inter-level (control) oxide can be reduced, without sacrificing the memory retention time. The present invention provides multi-layer chemical vapor deposition (CVD) poly-Si and thermal oxidation processes for fabricating a nano-Si quantum dots flash memory that addresses the issue of weakness in an insulating oxide.

Nanocrystal Si quantum dots embedded in silicon dioxide can be made using multi-layer CVD poly-Si and thermal oxidation processes. By controlling the poly-Si thickness and post-oxidation processes, the nano-Si particle size can be varied. X-ray and photoluminescence (PL) measurements can be used to measure nanocrystal Si quantum dot characteristics. The nanocrystal Si quantum dots have been integrated into flash memory devices, and these flash memory devices show excellent memory working functions. The memory windows are about 5-12 V, and the ratios of “on” current to “off” current are about 4-6 orders of magnitude. The data also shows that the operation voltage can be decreased and the memory retention improved, without increasing the tunneling oxide thickness.

Accordingly, a method is provided for forming a nanocrystal Si quantum dot memory device. The method comprises: forming a gate (tunnel) oxide layer overlying a Si substrate active layer; forming a nanocrystal Si memory film overlying the gate oxide layer, including a polycrystalline Si (poly-Si)/Si dioxide stack; forming a control Si oxide layer overlying the nanocrystal Si memory film; forming a gate electrode overlying the control oxide layer; and, forming source/drain regions in the Si active layer.

In one aspect, the nanocrystal Si memory film is formed by depositing a layer of amorphous Si (a-Si) using a chemical vapor deposition (CVD) process, and thermally oxidizing a portion of the a-Si layer. Typically, the a-Si deposition and oxidation processes are repeated, forming a plurality of poly-Si/Si dioxide stacks (i.e., 2 to 5 poly-Si/Si dioxide stacks).

In another aspect, each a-Si layer has a thickness in the range of about 2 to 10 nanometers (nm), and about 10 to 80% of a-Si layer is thermally oxidized. The Si nanocrystals formed typically have a diameter in the range of about 1 to 30 nm.

Additional details of the above-described method and a nanocrystal Si quantum dot memory device are provided below.

### BRIEF DESCRIPTION OF THE DRAWINGS

FIG. 1 is a partial cross-sectional view of a nanocrystal silicon (Si) quantum dot memory device.

FIG. 2 is a partial cross-section view of the memory device of FIG. 1, including additional details.

FIG. 3 depicts the x-ray patterns of polysilicon thin films as-deposited, and after post-annealing.

FIG. 4 depicts the formation of nanocrystal polysilicon after thermal oxidation.

FIG. 5 depicts the relationship between the oxidation thickness of polysilicon and the oxidation time.

FIG. 6 depicts the x-ray patterns of a nano-Si particle structure, after forming 3-5 layers (stacks) of a polysilicon Si/SiO2 super lattice, with various deposition times.

FIGS. 7A through 7F are partial cross-sectional views showing steps in the completion of the nanocrystal Si quantum dot memory device.

FIG. 8 depicts the drain currents (I_{D}) of a typical nano-Si quantum dot flash memory device as a function of gate voltage.

FIG. 9 depicts the drain current (I_{D}) vs. drain voltage (V_{D}) with various programming for a 10×10 μm device, with 5 nm of tunneling oxide and a nano-Si particle size of 2 nm.

FIG. 10 depicts the drain currents (I_{D}) of a nano-Si quantum dot flash memory device with a device size of 10×10 μm, a 5 nm tunneling oxide, and a nano-Si particle size of 3 nm, as a function of gate voltage.

FIG. 11 depicts the drain current (I_{D}) vs. drain voltage (V_{D}) with various programming of a 10×10 μm device, with a 5 nm tunneling oxide thickness, and a nano-Si particle size of 3 nm.

FIG. 12 depicts the drain currents (I_{D}) of a nano-Si quantum dot flash memory device with a device size of 20×20 μm, a 5 nm tunneling oxide thickness, and a nano-Si particle size of 4 nm, as a function of gate voltage.

FIG. 13 depicts the drain current (I_{D}) vs. drain voltage (V_{D}) with various programming of a 20×20 μm device, with a 5 nm tunneling oxide thickness, and a nano-Si particle size of 4 nm.

FIG. 14 depicts the drain currents (I_{D}) of a nano-Si quantum dot flash memory device with a device size of 20×20 μm, a 8.2 nm tunneling oxide thickness, and a nano-Si particle size of 4 nm, as a function of gate voltage.

FIG. 15 depicts the drain current (I_{D}) vs. drain voltage (V_{D}) with various programming of a 20×20 μm device, with a 8.2 nm tunneling oxide thickness, and a nano-Si particle size of 4 nm.

FIG. 16 is a flowchart illustrating a method for forming a nanocrystal Si quantum dot memory device.

FIG. 17 is a flowchart illustrating a method for operating a nanocrystal Si quantum dot memory device.

### DETAILED DESCRIPTION

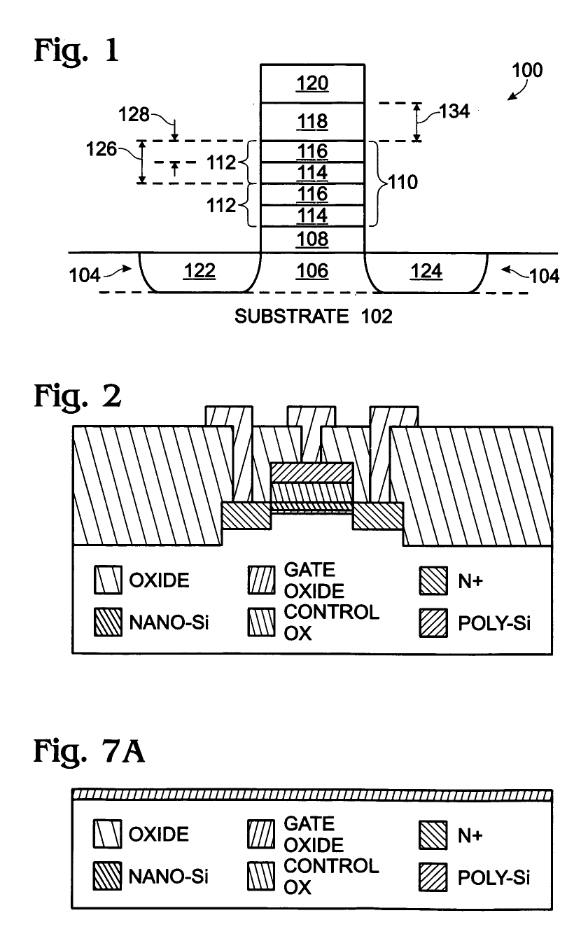

FIG. 1 is a partial cross-sectional view of a nanocrystal silicon (Si) quantum dot memory device. The memory device 100 comprises a Si substrate 102 having a Si active layer 104 with a channel region 106, as is conventional with an MOSFET device. A gate oxide layer 108 overlies the channel region 106. The gate oxide layer 108 is also referred to a tunneling oxide layer. A nanocrystal Si film 110, which is referred to herein as a memory film, overlies the gate oxide layer 108. The nanocrystal Si memory film 110 is also known as a floating gate (FG). The nanocrystal Si memory film 110 includes at least one polycrystalline Si (poly-Si)/Si dioxide stack 112, where each stack includes a poly-Si layer 114 and a Si dioxide layer 116.

A control Si oxide layer 118 overlies the nanocrystal Si memory film 110. A gate electrode 120, or control gate (CG), overlies the control oxide layer 118. The gate electrode 120 can be poly-Si or a metal, for example. As is conventional, source/drain (S/D) regions 122 and 124 are formed in the Si active layer 104, adjacent the channel region 106.

As implied above, the nanocrystal Si memory film 110 typically includes a plurality of poly-Si/Si dioxide stacks 112. Although two stacks 112 are shown, there can be about 2 to 5 poly-Si/Si dioxide stacks 112 in the nanocrystal Si memory film 110.

Each poly Si/Si dioxide stack 112 has a stack thickness 126, and the Si dioxide portion of each stack has a thickness 128 that is about 10 to 80% of the stack thickness 126. Each poly Si/Si dioxide stack 112 has a stack thickness 126 in the range of about 2 to 10 nanometers (nm).

In one aspect, the Si nanocrystals (not shown) in the nanocrystal Si memory film 110 have a diameter in the range of about 1 to 30 nm. In another aspect, the control oxide layer 118 has a thickness 134 in the range of 10 to 50 nm.

### Functional Description

The above-described nanocrystal Si quantum dot memory device can be fabricated using multi-layer CVD poly-Si deposition, post-annealing, and thermal oxidation processes.

FIG. 2 is a partial cross-section view of the memory device of FIG. 1, including additional details. A CVD process can be used to deposit a very thin polysilicon layer of about 2-5 nm. Then, a thermal oxidation process converts about 10-80% of the polysilicon into silicon dioxide. After repeating two or more cycles of polysilicon CVD deposition and thermal oxidation processes, nano-Si particles can be obtained. The CVD polysilicon deposition and thermal oxidation processes are shown in Tables 1 and 2.

TABLE 1
CVD polysilicon deposition process conditions

| Silane flow | Deposition temp. | Deposition pressure | Deposition time |
|---|---|---|---|
| 40-200 sccm | 500-600° C. | 150-250 mtorr | 1-10 min. for |
| | | | each layer |

TABLE 2
Thermal oxide process conditions

| | Nitrogen | Oxidation | Oxidation | |
|---|---|---|---|---|
| Oxygen flow | flow | temp. | pressure | Oxidation time |
| 1.6 SLPM | 8 SLPM | 700-1100° C. | atmosphere | 5-60 min. for |
| | | | | each layer |

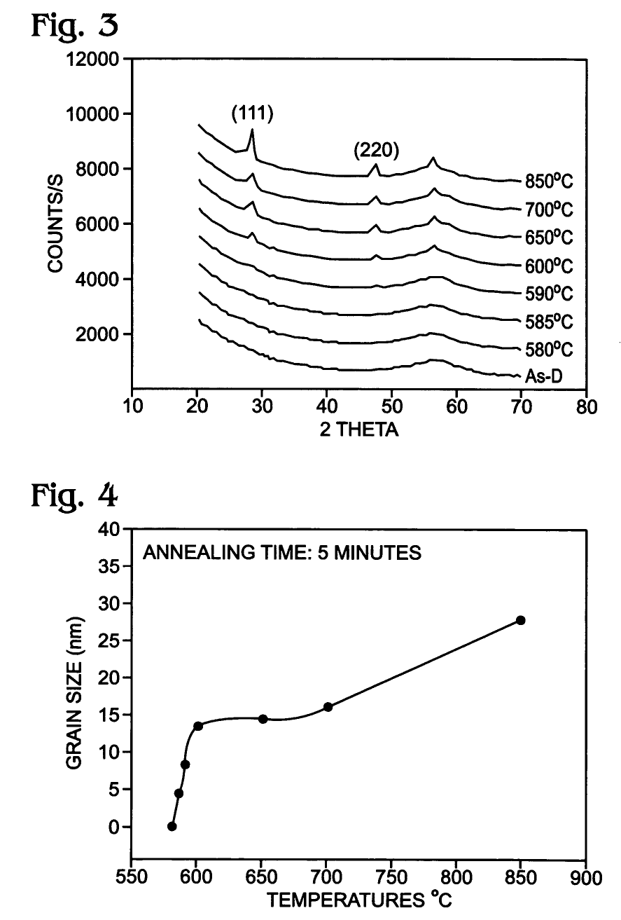

FIG. 3 depicts the x-ray patterns of polysilicon thin films as-deposited, and after post-annealing. The as-deposited polysilicon is amorphous. After post-annealing around 590° C., very small peaks appear at 28.2 and 47.1 degrees, which is evidence that the nucleation of polysilicon crystallization has occurred. With increased post-annealing temperatures, the counts of two peaks increase, which is proof that the grain size of polysilicon has also increased.

FIG. 4 depicts the formation of nanocrystal polysilicon after thermal oxidation. The grain size of polysilicon increases from a few nm, to 30 nm, as the thermal oxidation temperature increases from 560° C. to 850° C.

The grain size of the nano-Si particles is also controlled by polysilicon film thickness and the oxidation thickness. The grain size of the polysilicon decreases with a decrease in the film thickness of polysilicon, and also decreases with an increase in thermal oxidation thickness.

FIG. 5 depicts the relationship between the oxidation thickness of polysilicon and the oxidation time. The graph shows that the deposition and oxidation time of polysilicon can be controlled to achieve the desired nanocrystal Si grain size.

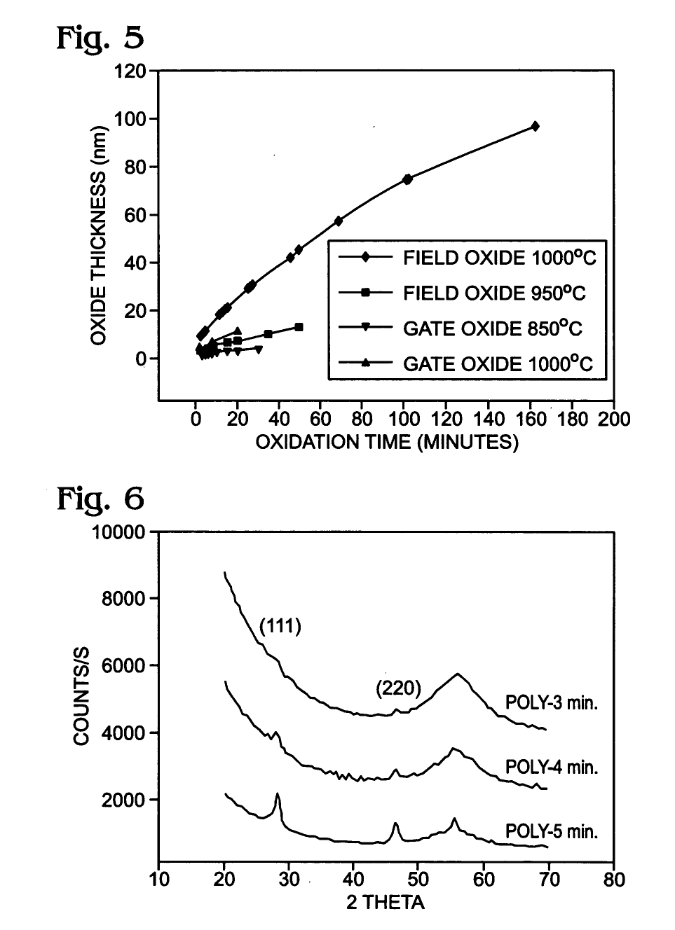

FIG. 6 depicts the x-ray patterns of a nano-Si particle structure, after forming 3-5 layers (stacks) of a polysilicon Si/SiO2 super lattice, with various deposition times. The thickness of the as-deposited polysilicon is about 3-10 nm for each layer, and the oxidation thickness for each layer is about 2-6 nm. The final grain size of the nanocrystal Si is about 1-5 nm, based upon x-ray calculations. Using these technologies, nanocrystal Si memory film can be made for a nano-Si quantum dots non-volatile flash memory.

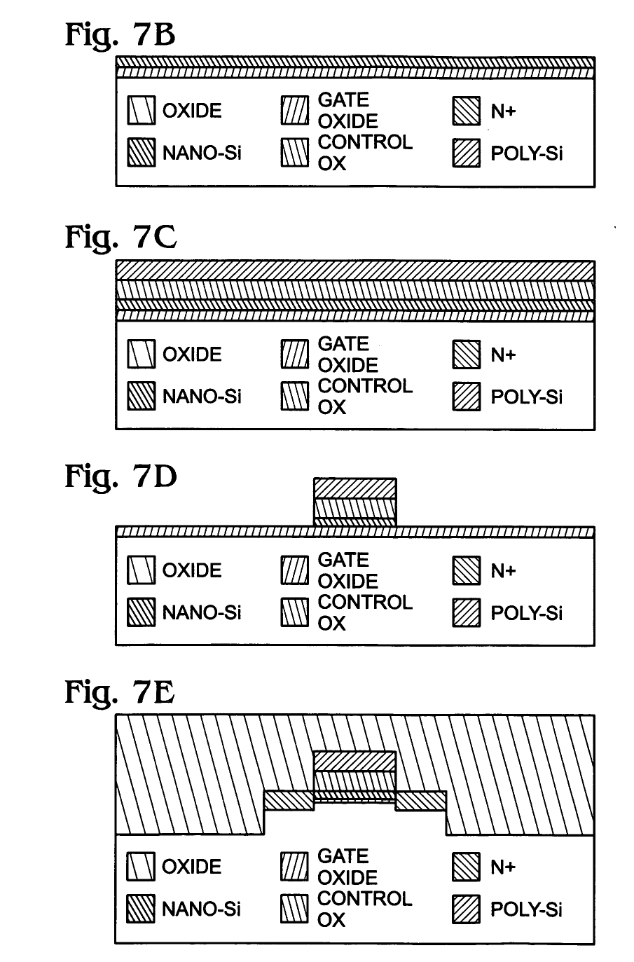

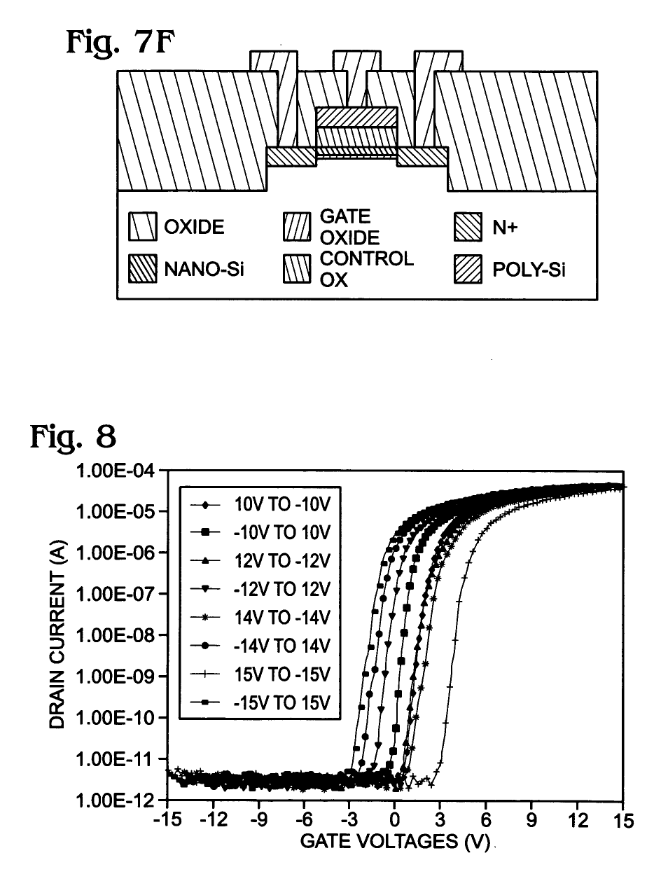

FIGS. 7A through 7F are partial cross-sectional views showing steps in the completion of the nanocrystal Si quantum dot memory device. P-type Si wafers were used as the nano-Si quantum dot flash memory device substrates.

FIG. 7A shows the well formation and the threshold voltage adjustment gate oxidation.

FIG. 7B shows the nano-Si particle deposition using CVD multilayer poly-Si and thermal oxidation processes.

FIG. 7C shows the CVD control oxide deposition and poly-Si gate deposition.

FIG. 7D shows the gate etching, which stops at the gate oxide.

FIG. 7E shows the source and drain implantation, and oxide deposition.

FIG. 7F shows the photoresist contact etching, first interconnect metallization, and final device structure.

FIG. 8 depicts the drain currents (I_{D}) of a typical nano-Si quantum dot flash memory device as a function of gate voltage. Using the above-described integration processes, high quality nano-Si quantum dot flash memory devices with device sizes of 10×10, 20×20, and 50×20 micrometers (μm) have been fabricated. For a 10×10 μm device, with a 5 nm tunneling oxide, and a nano-Si particle size of 2 nm, the drain voltage is kept constant at 0.1V. The drain junction leakage current of the device is very small (about 1 PA) and does not affect the memory properties of the device. After programming to “off” state, the drain current (I_{D}) at V_{D} of 0.1V and V_{G} of 2 V is about 1×10⁻¹² A. The “on” state drain current (I_{D}) at V_{D} of 0.1V and V_{G} of 2 V immediately after programming is about 5×10⁻⁵ A, which is 7 orders of magnitude higher than that of “off” state.

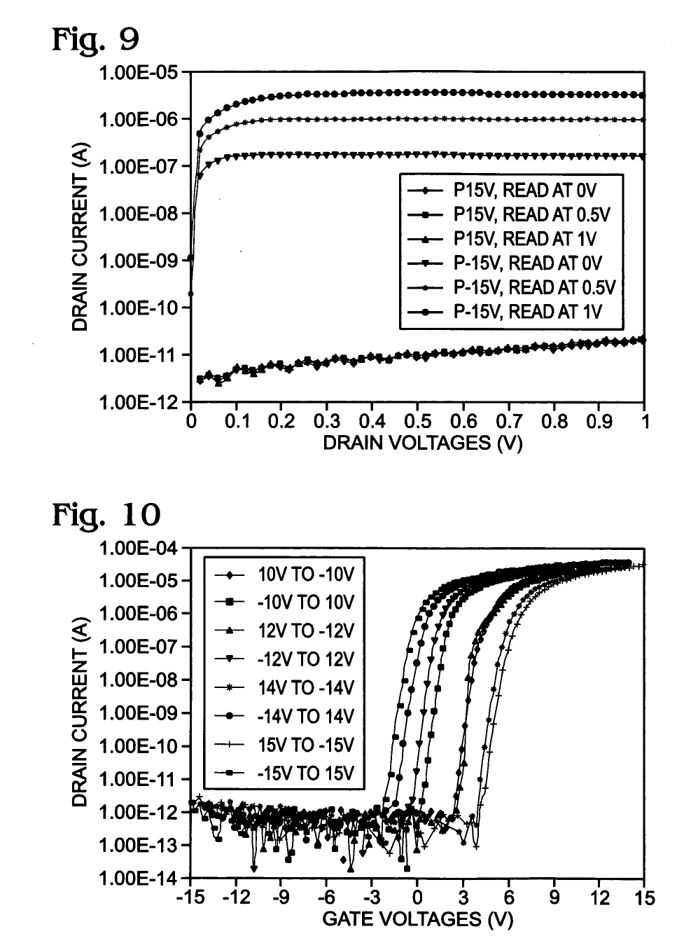

FIG. 9 depicts the drain current (I_{D}) vs. drain voltage (V_{D}) with various programming for a 10×10 μm device, with 5 nm of tunneling oxide, and a nano-Si particle size of 2 nm. After programming to “on” or “off” state, the drain current read at 1V is about 5×10⁻⁶ A and 1×10⁻¹¹A, respectively. The ratio of “on” current to “off” current is about 6 orders, which is consistent with I_{D} vs. V_{G} measurements in FIG. 8.

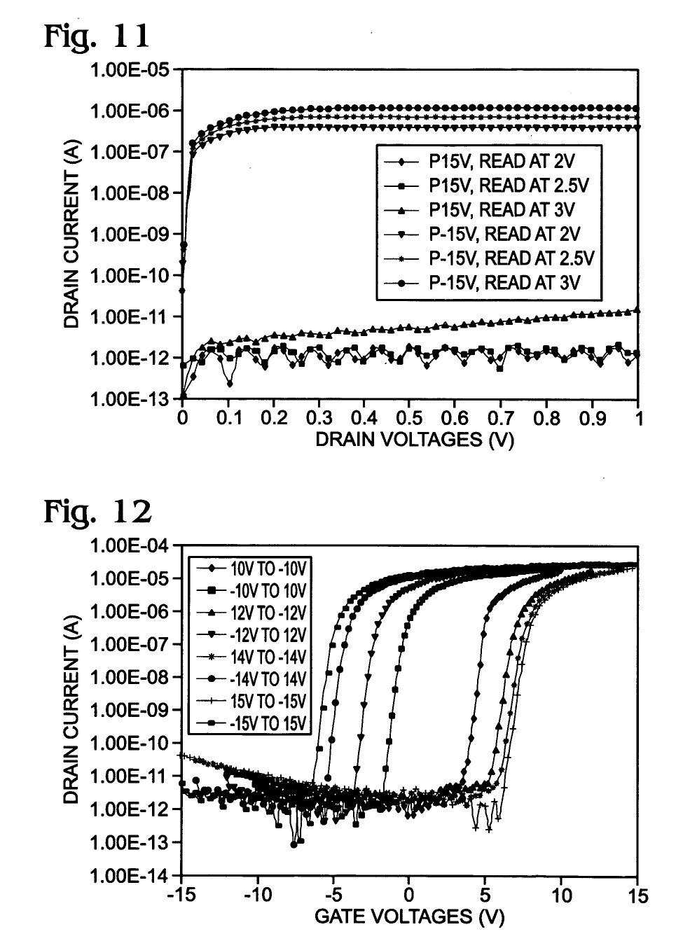

FIG. 10 depicts the drain currents (I_{D}) of a nano-Si quantum dot flash memory device with a device size of 10×10 μm, a 5 nm tunneling oxide, and a nano-Si particle size of 3 nm, as a function of gate voltage. The drain voltage is kept constant at 0.1V. The drain junction leakage current of the device is very small, about 1 PA, and does not affect the memory properties of the device. After programming to “off” state, the drain current (I_{D}) at V_{D} of 0.1V and V_{G} of 2 V is about 1×10¹² A. The “on” state drain current (I_{D}) at V_{D} of 0.1V and V_{G} of 2 V immediately after programming is about 5×10⁻⁴ A, which is 8 orders higher than that of “off” state.

FIG. 11 depicts the drain current (I_{D}) vs. drain voltage (V_{D}) with various programming of a 10×10 μm device, with a 5 nm tunneling oxide thickness, and a nano-Si particle size of 3 nm. After programming to “on” or “off” state, the drain current read at 1V is about 1×10⁻⁵ A and 1×10⁻¹²A, respectively. The ratio of “on” current to “off” current is about 7 orders, which is consistent with I_{D} vs. V_{G} measurements of FIG. 10.

FIG. 12 depicts the drain currents (I_{D}) of a nano-Si quantum dot flash memory device with a device size of 20×20 μm, a 5 nm tunneling oxide thickness, and a nano-Si particle size of 4 nm, as a function of gate voltage. The drain voltage is kept constant at 0.1V. The drain junction leakage current of the device is very small, at about 1 PA, and does not affect the memory properties of the device. After programming to “off” state, the drain current (I_{D}) at V_{D} of 0.1V and V_{G} of 2 V is about 1×10⁻¹² A. The “on” state drain current (I_{D}) at V_{D} of 0.1V and V_{G} of 2 V immediately after programming is about 4×10⁻⁴ A, which is 8 orders higher than that of “off” state.

FIG. 13 depicts the drain current (I_{D}) vs. drain voltage (V_{D}) with various programming of a 20×20 μm device, with a 5 nm tunneling oxide thickness, and a nano-Si particle size of 4 nm. After programming to “on” or “off” state, the drain current read at 1V is about 5×10⁻⁴ A and 5×10⁻¹²A, respectively. The ratio of “on” current to “off” current is about 8 orders, which is consistent with I_{D} vs. V_{G} measurements in FIG. 12.

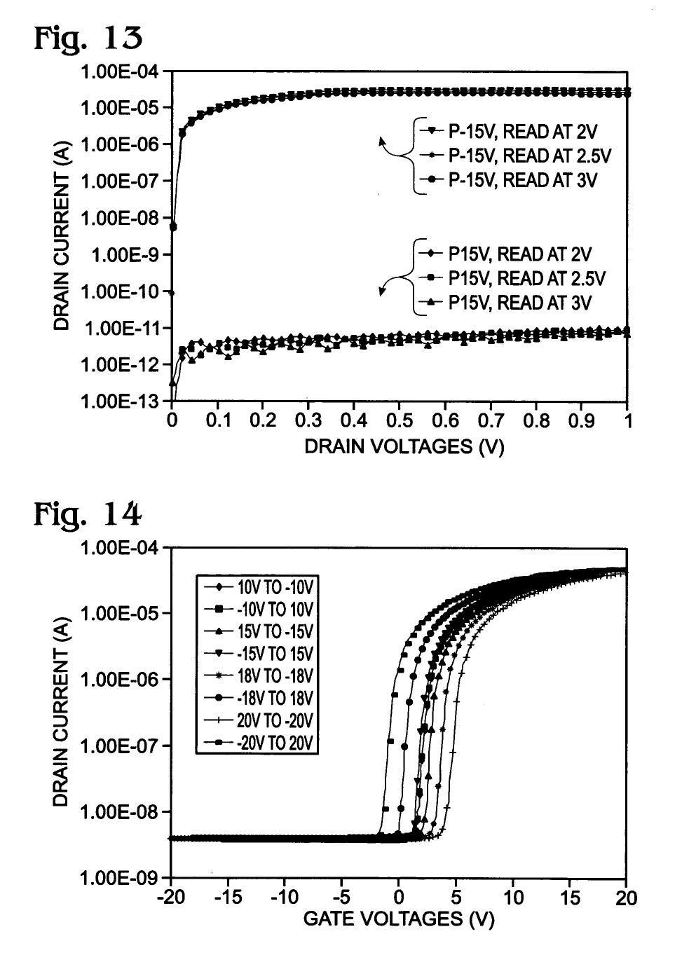

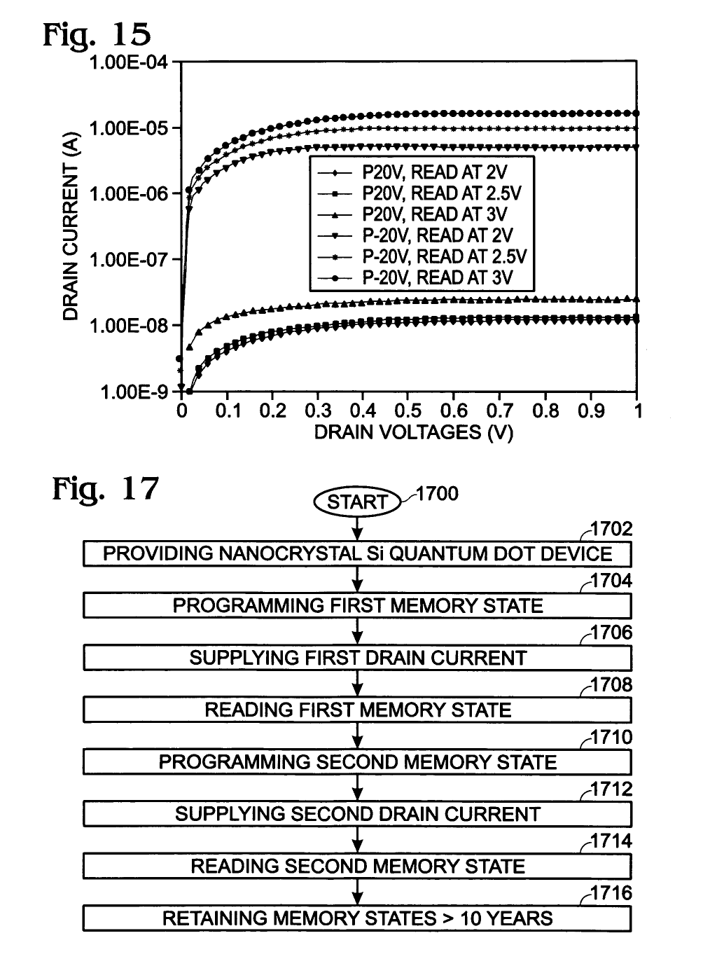

FIG. 14 depicts the drain currents (I_{D}) of a nano-Si quantum dot flash memory device with a device size of 20×20 μm, a 8.2 nm tunneling oxide thickness, and a nano-Si particle size of 4 nm, as a function of gate voltage. The drain voltage is kept constant at 0.1V. The drain junction leakage current of the device is about 0.1 nA. After programming to “off” state, the drain current (I_{D}) at V_{D} of 0.1V and V_{G} of 0 V is about 5×10⁻⁹ A. The “on” state drain current (I_{D}) at V_{D} of 0.1V and V_{G} of 2 V immediately after programming is about 6×10⁻⁴ A, which is 4 orders high than that of “off” state.

FIG. 15 depicts the drain current (I_{D}) vs. drain voltage (V_{D}) with various programming of a 20×20 μm device, with a 8.2 nm tunneling oxide thickness, and a nano-Si particle size of 4 nm. After programming to “on” or “off” state, the drain current read at 1V is about 2×10⁻⁵ A and 1×10⁻⁸A, respectively. The ratio of “on” current to “off” current is about 3 orders, which is consistent with I_{D} vs. V_{G} measurements in FIG. 14.

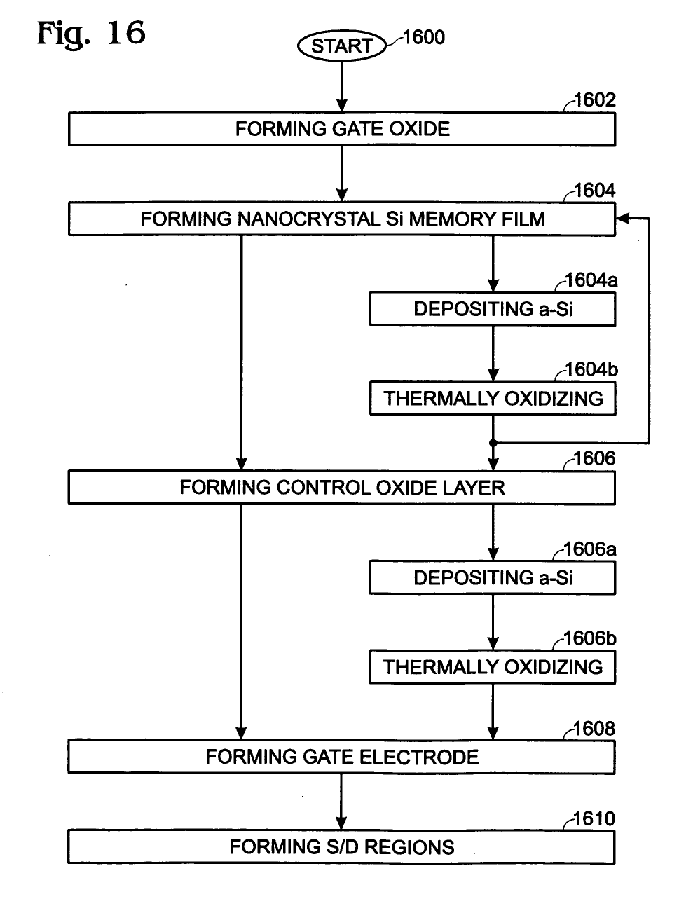

FIG. 16 is a flowchart illustrating a method for forming a nanocrystal Si quantum dot memory device. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1600.

Step 1602 forms a gate (tunnel) oxide layer overlying a Si substrate active layer. Step 1604 forms a nanocrystal Si memory film overlying the gate oxide layer. The nanocrystal Si memory film includes a poly-Si/Si dioxide stack. Step 1606 forms a control Si oxide layer overlying the nanocrystal Si memory film. Step 1608 forms a (control) gate electrode overlying the control oxide layer. Step 1610 forms source/drain (S/D) regions in the Si active layer. It should be understood that these steps are intended to describe the fabrication of both NOR and NAND flash memory devices.

Typically, forming the nanocrystal Si memory film in Step 1604 includes forming Si nanocrystals having a diameter in the range of about 1 to 30 nm. In another aspect, forming the nanocrystal Si memory film in Step 1604 includes substeps. Step 1604a deposits a layer of amorphous Si (a-Si) using a CVD process. Step 1604b thermally oxidizes a portion of the a-Si layer. Typically, forming the nanocrystal Si memory film in Step 1604 includes repeating the a-Si deposition and oxidation processes (Steps 1604a and 1604b), forming a plurality of poly-Si/Si dioxide stacks. For example, about 2 to 5 poly-Si/Si dioxide stacks may be formed.

In one aspect, thermally oxidizing a portion of the a-Si in Step 1604b includes thermally oxidizing in the range of about 10 to 80% of a-Si layer. In another aspect, depositing the layer of a-Si in Step 1604a includes depositing a layer of a-Si having a thickness in the range of about 2 to 10 nm.

In one aspect, depositing the layer of a-Si in Step 1604a includes additional substeps (not shown). Step 1604a1 introduces Silane at a flow rate in the range of about 40 to 200 standard cubic centimeters (sccm). Step 1604a2 heats the substrate to a temperature in the range of about 500 to 600° C. Step 1604a3 establishes a deposition pressure in the range of about 150 to 250 milli-torr (mtorr). Step 1604a4 deposits for a duration in the range of about 1 to 5 minutes.

In a different aspect, thermally oxidizing the portion of the a-Si layer in Step 1604b includes additional substeps (not shown). Step 1604b1 introduces oxygen at a flow rate of about 1.6 standard liters per minute (SLPM). Step 1604b2 introduces nitrogen at a flow rate of about 8 SLPM. Step 1604b3 heats the substrate to a temperature in the range of about 700 to 1100° C. Step 1604b4 establishes an oxidation pressure of about ambient atmosphere, and Step 1604b5 oxidizes for a duration in the range of about 5 to 60 minutes.

In one aspect, forming the control Si oxide layer in Step 1606 includes substeps. Step 1606a deposits a-Si using a deposition process such as CVD or sputtering. Step 1606b thermally oxidizes the a-Si. Typically, the control Si oxide layer has a thickness in the range of about 10 to 50 nm. Alternately, Step 1606 deposits Si oxide using either a CVD or sputtering process.

In one aspect, forming the nanocrystal Si memory film includes decreasing the thickness of the deposited a-Si layer (Step 1604a). The nanocrystal Si grain size decreases in response to the decreased thickness of the deposited a-Si layer. In a different aspect, Step 1604b increases the portion of a-Si layer thermally oxidized. The nanocrystal Si grain size decreases in response to an increase in the thickness of the Si dioxide in the stack.

FIG. 17 is a flowchart illustrating a method for operating a nanocrystal Si quantum dot memory device. The method starts at Step 1700. Step 1702 provides a Si quantum dot memory device with a Si substrate, a Si active layer with a channel region, a gate oxide layer overlying the channel region, a nanocrystal Si film overlying the gate oxide layer, including a polycrystalline Si (poly-Si)/Si dioxide stack, a control Si oxide layer overlying the nanocrystal Si film, a gate electrode overlying the control oxide layer, and source/drain regions in the Si active layer, adjacent the channel region (see the description of FIG. 1).

Step 1704 programs the device to a first memory state. Step 1706 supplies a first drain current responsive to the first memory state. Step 1708 reads the first memory state in response to the first drain current. Step 1710 programs the device to a second memory state. Step 1712 supplies a second drain current responsive to the second memory state, at least 6 orders of magnitude larger than the first drain current. Step 1714 reads the second memory state in response to the second drain current, see the description of FIGS. 8-15 above.

In one aspect, providing a Si quantum dot memory device in Step 1702 includes providing a device with a gate oxide thickness in the range of about 3 to 10 nm and a control oxide thickness about 1.5 to 3 times greater than the gate oxide thickness. Programming the first and second memory states in Steps 1704 and 1710, respectively, includes supplying a drain voltage of less than 20 volts. Step 1716 retains the first and second memory states for a duration of longer than 10 years.

A nanocrystal Si quantum dot memory device has been provided, along with an associated fabrication process. Materials and process details have been given as examples to illustrate the invention. However, the invention is not limited to merely these examples. Other variations and embodiments of the invention will occur to those skilled in the art.

We claim:

1. A method for forming a nanocrystal silicon (Si) quantum dot memory device, the method comprising:
forming a gate oxide layer overlying a Si substrate active layer;
forming a nanocrystal Si memory film overlying the gate oxide layer, including a polycrystalline Si (poly-Si)/Si dioxide stack;
forming a control Si oxide layer overlying the nanocrystal Si memory film;
forming a gate electrode overlying the control oxide layer; and,
forming source/drain regions in the Si active layer.

2. The method of claim 1 wherein forming the nanocrystal Si memory film overlying the gate oxide layer includes:
depositing a layer of amorphous Si (a-Si) using a chemical vapor deposition (CVD) process; and,
thermally oxidizing a portion of the a-Si layer.

3. The method of claim 2 wherein forming the nanocrystal Si memory film overlying the gate oxide layer includes repeating the a-Si deposition and oxidation processes, forming a plurality of poly-Si/Si dioxide stacks.

4. The method of claim 3 wherein forming the plurality of poly-Si/Si dioxide stacks includes forming about 2 to 5 poly-Si/Si dioxide stacks.

5. The method of claim 2 wherein thermally oxidizing a portion of the a-Si includes thermally oxidizing in the range of about 10 to 80% of a-Si layer.

6. The method of claim 2 wherein depositing the layer of a-Si includes depositing a layer of a-Si having a thickness in the range of about 2 to 10 nanometers (nm).

7. The method of claim 2 wherein depositing the layer of a-Si includes:
introducing Silane at a flow rate in the range of about 40 to 200 standard cubic centimeters (sccm);
heating the substrate to a temperature in the range of about 500 to 600° C.;
establishing a deposition pressure in the range of about 150 to 250 milli-torr (mtorr); and,
depositing for a duration in the range of about 1 to 5 minutes.

8. The method of claim 2 wherein thermally oxidizing the portion of the a-Si layer includes:
introducing oxygen at a flow rate of about 1.6 standard liters per minute (SLPM);
introducing nitrogen at a flow rate of about 8 SLPM;
heating the substrate to a temperature in the range of about 700 to 1100° C.;
establishing an oxidation pressure of about ambient atmosphere; and,
oxidizing for a duration in the range of about 5 to 60 minutes.

9. The method of claim 1 wherein forming the nanocrystal Si memory film overlying the gate oxide layer includes forming Si nanocrystals having a diameter in the range of about 1 to 30 nm.

10. The method of claim 1 wherein forming the control Si oxide layer includes:
depositing a-Si using a deposition process selected from the group consisting of chemical vapor deposition (CVD) and sputtering; and,
thermally oxidizing the a-Si.

11. The method of claim 1 wherein forming the control Si oxide layer includes forming a Si oxide layer having a thickness in the range of about 10 to 50 nm.

12. The method of claim 2 wherein forming the nanocrystal Si memory film includes decreasing the thickness of the deposited a-Si layer; and,
decreasing the nanocrystal Si grain size in response to the decreased thickness of the deposited a-Si layer.

13. The method of claim 2 wherein forming the nanocrystal Si memory film includes increasing the portion of a-Si layer thermally oxidized; and,
decreasing the nanocrystal Si grain size in response to an increase in the thickness of the Si dioxide in the stack.

14. A nanocrystal silicon (Si) quantum dot memory device, the memory device comprising:
a Si substrate having a Si active layer with a channel region;
a gate oxide layer overlying the channel region;
a nanocrystal Si memory film overlying the gate oxide layer, including a polycrystalline Si (poly-Si)/Si dioxide stack;
a control Si oxide layer overlying the nanocrystal Si memory film;
a gate electrode overlying the control oxide layer; and,
source/drain regions in the Si active layer, adjacent the channel region.

15. The memory device of claim 14 wherein the nanocrystal Si memory film includes a plurality of poly-Si/Si dioxide stacks.

16. The memory device of claim 15 wherein the nanocrystal Si memory film includes about 2 to 5 poly-Si/Si dioxide stacks.

17. The memory device of claim 15 wherein each poly Si/Si dioxide stack has a stack thickness, and the Si dioxide portion of each stack has a thickness that is about 10 to 80% of the stack thickness.

18. The memory device of claim 15 wherein each poly Si/Si dioxide stack has a stack thickness in the range of about 2 to 10 nanometers (nm).

19. The memory device of claim 14 wherein the nanocrystal Si memory film includes Si nanocrystals having a diameter in the range of about 1 to 30 nm.

20. The memory device of claim 14 where the control oxide layer has a thickness in the range of 10 to 50 nm.

21. A method for operating a nanocrystal silicon (Si) quantum dot memory device, the method comprising:
providing a Si quantum dot memory device with a Si substrate, a Si active layer with a channel region, a gate oxide layer overlying the channel region, a nanocrystal Si film overlying the gate oxide layer, including a polycrystalline Si (poly-Si)/Si dioxide stack, a control Si oxide layer overlying the nanocrystal Si film, a gate electrode overlying the control oxide layer, and source/drain regions in the Si active layer, adjacent the channel region;
programming the device to a first memory state;
supplying a first drain current responsive to the first memory state;
in response to the first drain current, reading the first memory state;
programming the device to a second memory state;
supplying a second drain current responsive to the second memory state, at least 6 orders of magnitude larger than the first drain current; and,
in response to the second drain current, reading the second memory state.

22. The method of claim 21 wherein providing a Si quantum dot memory device includes providing a device with a gate oxide thickness in the range of about 3 to 10 nanometers (nm) and a control oxide thickness about 1.5 to 3 times greater than the gate oxide thickness;
wherein programming the first and second memory states includes supplying a drain voltage of less than 20 volts; and,
the method further comprising:
retaining the first and second memory states for a duration of longer than 10 years.
